(19) United States
(12) Patent Application Publication
(10) Pub. No.: US 2013/0298831 A1
(43) Pub. Date: Nov. 14, 2013

(54) AUTOMATED PROCESS CHAMBER CLEANING IN MATERIAL DEPOSITION SYSTEMS

(71) Applicants: Bassam Shamoun, Basking Ridge, NJ (US); Alex Gurary, Bridgewater, NJ (US); Vadim Boguslavskiy, Princeton, NJ (US); Matthew King, Montville, NJ (US); Lukas Urban, Princeton, NJ (US)

(72) Inventors: Bassam Shamoun, Basking Ridge, NJ (US); Alex Gurary, Bridgewater, NJ (US); Vadim Boguslavskiy, Princeton, NJ (US); Matthew King, Montville, NJ (US); Lukas Urban, Princeton, NJ (US)

(21) Appl. No.: 13/471,068

(22) Filed: May 14, 2012

(51) Int. Cl. B08B 9/087; C23C 16/46; A46B 15/00

(52) U.S. Cl. 118/725; 15/56; 134/8

(57) ABSTRACT

A cleaning carrier for in-situ cleaning of a process chamber of a material deposition tool and method for in-situ cleaning using a cleaning carrier. The cleaning carrier includes a body formed symmetrically about a central axis and having a geometry generally corresponding to the geometry of the removable wafer carrier for use with the tool, and a tool interface that facilitates mounting of the cleaning carrier body on a portion of the material deposition tool that accepts the removable wafer carrier. A set of deployable and retractable brushes are operatively coupled with the cleaning carrier body via a corresponding set of deployment and retraction mechanisms, the brushes being movable between a retracted position for handling of the cleaning carrier and a deployed position for cleaning an interior surface of the process chamber.

### FIELD OF THE INVENTION

The invention relates generally to semiconductor fabrication technology and, more particularly, to cleaning material deposits from interior surfaces of wafer processing systems such as chemical vapor deposition (CVD) apparatus.

### BACKGROUND OF THE INVENTION

In the fabrication of light-emitting diodes (LEDs) and other high-performance devices such as laser diodes, optical detectors, and field effect transistors, a chemical vapor deposition (CVD) process is typically used to grow a thin film stack structure using materials such as gallium nitride over a sapphire or silicon substrate. A CVD tool includes a process chamber, which is a sealed environment that allows infused gases to be deposited upon the substrate (typically in the form of wafers) to grow the thin film layers. An example of a current product line of such manufacturing equipment is the TurboDisc® family of MOCVD systems, manufactured by Veeco Instruments Inc. of Plainview, N.Y.

A number of process parameters are controlled, such as temperature, pressure and gas flow rate, to achieve a desired crystal growth. Different layers are grown using varying materials and process parameters. For example, devices formed from compound semiconductors such as III-V semiconductors typically are formed by growing successive layers of the compound semiconductor using metal organic chemical vapor deposition (MOCVD). In this process, the wafers are exposed to a combination of gases, typically including a metal organic compound as a source of a group III metal, and also including a source of a group V element which flow over the surface of the wafer while the wafer is maintained at an elevated temperature. Typically, the metal organic compound and group V source are combined with a carrier gas which does not participate appreciably in the reaction as, for example, nitrogen. One example of a III-V semiconductor is gallium nitride, which can be formed by reaction of an organo-gallium compound and ammonia on a substrate having a suitable crystal lattice spacing, as for example, a sapphire wafer. Typically, the wafer is maintained at a temperature on the order of 1000-1100° C. during deposition of gallium nitride and related compounds.

In a MOCVD process, where the growth of crystals occurs by chemical reaction on the surface of the substrate, the process parameters must be controlled with particular care to ensure that the chemical reaction proceeds under the required conditions. Even small variations in process conditions can adversely affect device quality and production yield. For instance, if a gallium and indium nitride layer is deposited, variations in wafer surface temperature will cause variations in the composition and bandgap of the deposited layer. Because indium has a relatively high vapor pressure, the deposited layer will have a lower proportion of indium and a greater bandgap in those regions of the wafer where the surface temperature is higher. If the deposited layer is an active, light-emitting layer of an LED structure, the emission wavelength of the LEDs formed from the wafer will also vary to an unacceptable degree.

In a MOCVD process chamber, semiconductor wafers on which layers of thin film are to be grown are placed on rapidly-rotating carousels, referred to as wafer carriers, to provide a uniform exposure of their surfaces to the atmosphere within the reactor chamber for the deposition of the semiconductor materials. Rotation speed is on the order of 1,000 RPM. The wafer carriers are typically machined out of a highly thermally conductive material such as graphite, and coated with a protective layer of a material such as silicon carbide. Each wafer carrier has a set of circular indentations, or pockets, in its top surface in which individual wafers are placed. Typically, the wafers are supported in spaced relationship to the bottom surface of each of the pockets to permit the flow of gas around the edges of the wafer. Some examples of pertinent technology are described in U.S. Patent Application Publication No. 2012/0040097, U.S. Pat. No. 8,092,599, U.S. Pat. No. 8,021,487, U.S. Patent Application Publication No. 2007/0186853, U.S. Pat. No. 6,902,623, U.S. Pat. No. 6,506,252, and U.S. Pat. No. 6,492,625, the disclosures of which are incorporated by reference herein.

The wafer carrier is supported on a spindle within the reaction chamber so that the top surface of the wafer carrier having the exposed surfaces of the wafers faces upwardly toward a gas distribution device. While the spindle is rotated, the gas is directed downwardly onto the top surface of the wafer carrier and flows across the top surface toward the periphery of the wafer carrier. The used gas is evacuated from the reaction chamber through ports disposed below the wafer carrier. The wafer carrier is maintained at the desired elevated temperature by heating elements, typically electrical resistive heating elements disposed below the bottom surface of the wafer carrier. These heating elements are maintained at a temperature above the desired temperature of the wafer surfaces, whereas the gas distribution device typically is maintained at a temperature well below the desired reaction temperature so as to prevent premature reaction of the gases. Therefore, heat is transferred from the heating elements to the bottom surface of the wafer carrier and flows upwardly through the wafer carrier to the individual wafers.

A great deal of effort has been devoted to system design features to minimize temperature and flow variations during processing; however, the problem continues to present many challenges, especially in light of the need to process greater numbers of wafers, and larger-sized wafers, in each batch.

In order to minimize the effect of radiation heat loss and to improve the uniformity of the deposited material over the entire surface of the wafer carrier, a ring-shaped fixture called a flow extender is situated in close proximity surrounding the outer edge of the wafer carrier. During the MOCVD growth process the flow stream of non-reacted gases is redirected by the flow extender along a specific path to the chamber's exhaust. Behind the flow extender is situated a shutter mechanism that isolates the reaction space from the walls of the process chamber. As its name implies, the shutter operates to vent gasses in order to control pressure and flow characteristics in the reaction space.

As an unintended consequence, GaN materials are deposited on the surfaces of the flow extender and shutter. These deposits build up over time and over repeated processing cycles, and tend to adversely affect wafer processing. For example, the material deposited on the flow extender can desorb from the flow extender surface and flow back onto the wafers, resulting in excessive and non-uniform deposition on the wafers. The deposits can also continue to accumulate on the surface of the flow extender and adjacent fixtures, such as the shutter assembly, and cause changes in the gas flow pattern, creating eddy currents, etc., disrupting the intended boundary layer dynamics across the entire wafer carrier. The build-up of deposits further affects heat reflectivity from the coated structures. These effects cause variations in processing results and, ultimately, result in reduced product yields.

Currently, process chambers that utilize a flow extender must be subjected to regular cleanings every 15-30 runs. This frequent cleaning regiment represents an increase in the MOCVD tool preventive maintenance by a factor of four times that of a comparable tool without a flow extender. With each cleaning requiring opening and disassembling portions of the process chamber, the increased cleaning significantly diminishes factory throughput and overall yield, as well as increasing the cost of maintaining the tool.

In view of the above, a practical solution is needed to alleviate the burden of cleaning of material deposition systems.

### SUMMARY OF THE INVENTION

Aspects of the invention are directed to in situ cleaning of a material deposition tool's process chamber, such as a process chamber of a chemical vapor deposition (CVD) tool. The in-situ cleaning is achieved without having to disassemble the process chamber to perform the cleaning operation. Instead, according to solutions provided in accordance with embodiments of the invention, a cleaning mechanism is deployed that works with existing functionality of the material deposition tool itself.

In one aspect, a method is provided for in-situ cleaning of a process chamber of a material deposition tool that is adapted for use with a removable wafer carrier. The removable wafer carrier has an outer form factor defined based on predefined operational clearances within the process chamber. This method includes loading a specialized cleaning carrier into the process chamber in place of an ordinary wafer carrier. The material deposition tool executes a cleaning process that includes rotation of the cleaning carrier. During the cleaning process, the cleaning carrier deploys a set of deployable and retractable brushes such that at least one cleaning element of each brush contacts an interior surface of the process chamber and the rotation of the cleaning carrier causes that cleaning element to scrub the interior surface to remove material deposits from that surface. At the conclusion of the cleaning process the cleaning carrier retracts the set of brushes such that each of the cleaning elements of each of the brushes ceases contact with the interior surface of the process chamber. The cleaning carrier is then unloaded from the process chamber.

In one embodiment, a cleaning carrier includes a cleaning carrier body formed symmetrically about a central axis and having a geometry generally corresponding to the geometry of the removable wafer carrier such that the cleaning carrier body has outer boundaries within, the same as, or not substantially exceeding, the outer form factor of the removable wafer carrier. The cleaning carrier also includes a tool interface that facilitates mounting of the cleaning carrier body on a portion of the material deposition tool that accepts the removable wafer carrier, such as a spindle, for instance. A set of deployable and retractable brushes are operatively coupled with the cleaning carrier body via a corresponding set of deployment and retraction mechanisms. The brushes are movable between a retracted position and a deployed position such that in the retracted position, the brushes are situated within the outer form factor and, in the deployed position, the brushes protrude beyond the outer form factor.

In a particular embodiment, a process condition, such as rotation of the cleaning carrier, causes deployment of the brushes. In another particular embodiment, the cleaning carrier further includes an anti-slip mechanism constructed to engage and disengage a drive mechanism of the material deposition tool on which the wafer carrier rotates. The engagement with the drive mechanism increases a degree of coupling between the cleaning carrier body and the drive mechanism so as to reduce slippage between the drive mechanism and cleaning carrier during the rotation. In a related embodiment, the anti-slip mechanism is a clamping mechanism that is engaged in response to rotation of the cleaning carrier. Various other embodiments are described herein.

In a related aspect of the invention, a cleaning carrier such as the one described above is provided as part of a CVD apparatus that includes a process chamber, a rotatable spindle disposed inside the process chamber, a wafer carrier for transporting and providing a support for one or more wafers, and a heating element. The cleaning carrier is operated in place of the wafer carrier as part of carrying out a cleaning process.

In another aspect of the invention, a cleaning carrier includes a cleaning carrier body formed symmetrically about a central axis and having a geometry generally corresponding to the geometry of the removable wafer carrier, a tool interface, and at least one cleaning element adapted to clean an interior surface of the process chamber. The tool interface facilitates mounting of the cleaning carrier body on a portion of the material deposition tool that accepts the removable wafer carrier. The tool interface comprises an anti-slip mechanism operatively coupled to the cleaning carrier body and constructed to engage and disengage a drive mechanism of the material deposition tool on which the wafer carrier rotates during operation. The engagement with the drive mechanism increases a degree of coupling between the cleaning carrier body and the drive mechanism so as to reduce slippage between the drive mechanism and cleaning carrier during the rotation.

Likewise, in a related aspect of the invention, a cleaning carrier such as the one described above is provided as part of a greater CVD apparatus.

In other aspects of the invention, the anti-slip mechanism may be used as part of a wafer carrier to improve the coupling between the wafer carrier and the drive mechanism of the process chamber. The anti-slip mechanism may further be used with other specialized carriers, for cleaning, testing, calibration, or otherwise, to improve the coupling to the drive mechanism.

### BRIEF DESCRIPTION OF THE DRAWINGS

The invention may be more completely understood in consideration of the following detailed description of various embodiments of the invention in connection with the accompanying drawings, in which:

FIG. 1 illustrates a chemical vapor deposition (CVD) apparatus in accordance with one embodiment of the invention.

FIG. 2 is a perspective view diagram illustrating a typical wafer carrier used with the apparatus of FIG. 1 according to one embodiment of the invention.

FIG. 3 is a partial cut-away view diagram illustrating additional parts of the process chamber of the CVD system of FIG. 1 according to an example, in which a flow extender and shutter components are shown.

FIG. 4 is a diagram illustrating the interior of reaction space within the process chamber of FIG. 1 in which GaN deposits have formed on the surfaces of the shutter and flow extender.

FIG. 5 is a schematic diagram illustrating a cleaning carrier for efficient in-situ removal of undesired material deposits such as those shown in FIG. 4 according to various aspects of the invention.

FIG. 6 is a top view diagram illustrating an exemplary cleaning carrier in greater detail according to one embodiment.

FIGS. 7A and 7B illustrate in perspective view brush deployment and retraction mechanism of the cleaning carrier of FIG. 6, with the brush retracted and deployed, respectively.

FIG. 8 is a side-view diagram of a brush and deployment and retraction mechanism of a cleaning carrier according to one embodiment in which additional details are shown.

FIG. 9 is a perspective view diagram illustrating another example of a cleaning carrier according to another embodiment of the cleaning carrier of FIG. 5.

FIG. 10 is a partial cut-away diagram illustrating a brush and deployment/retraction mechanism in greater detail according to a related embodiment.

FIG. 11 is a schematic diagram illustrating a cleaning carrier that features an anti-slip spindle clamping mechanism according to one embodiment.

FIG. 12 is a close-up view diagram of the spindle clamping part of the clamp mechanism of FIG. 11 according to one embodiment.

FIG. 13 is a close-up view diagram of the clamping mechanism activation portion according to one embodiment.

FIGS. 14A-14B illustrate the spindle clamping part and activation part, respectively, of the clamping mechanism in the disengaged state, whereas

FIGS. 15A-15B are counterpart illustrations showing both parts of the clamping mechanism in the engaged state according to one embodiment.

FIG. 16 is a flow diagram illustrating a process for using a cleaning carrier to clean interior surfaces of a material deposition tool according to one embodiment.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

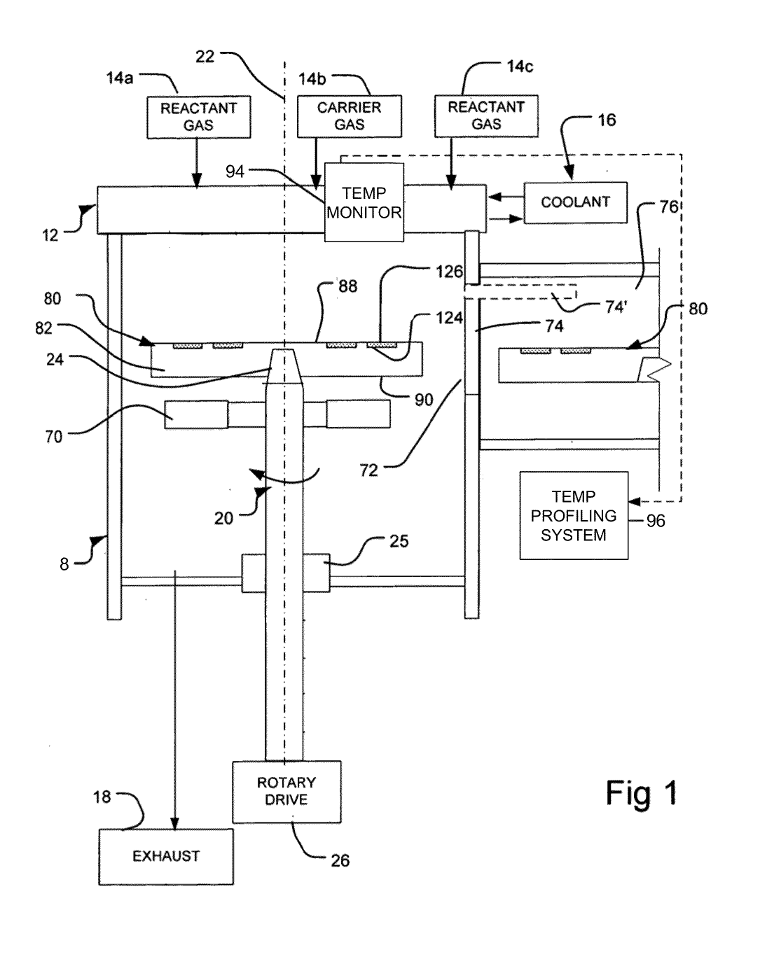

FIG. 1 illustrates a chemical vapor deposition (CVD) apparatus in accordance with one embodiment of the invention. A reaction chamber 8 defines a process environment space. A gas distribution device 12 is arranged at one end of the chamber. The end having the gas distribution device 12 is referred to herein as the “top” end of the chamber 8. This end of the chamber typically, but not necessarily, is disposed at the top of the chamber in the normal gravitational frame of reference. Thus, the downward direction as used herein refers to the direction away from the gas distribution device 12; whereas the upward direction refers to the direction within the chamber, toward the gas distribution device 12, regardless of whether these directions are aligned with the gravitational upward and downward directions. Similarly, the “top” and “bottom” surfaces of elements are described herein with reference to the frame of reference of chamber 8 and gas distribution device 12.

Gas distribution device 12 is connected to sources 14a, 14b, 14c for supplying process gases to be used in the wafer treatment process, such as a carrier gas and reactant gases such as a metalorganic compound and a source of a group V metal. The gas distribution device 12 is arranged to receive the various gases and direct a flow of process gasses generally in the downward direction. The gas distribution device 12 desirably is also connected to a coolant system 16 arranged to circulate a liquid through the gas distribution device so as to maintain the temperature of the gas distribution device at a desired temperature during operation. A similar coolant arrangement (not shown) can be provided for cooling the walls of chamber 8. Chamber 8 is also equipped with an exhaust system 18 arranged to remove spent gases from the interior of the chamber through ports (not shown) at or near the bottom of the chamber so as to permit continuous flow of gas in the downward direction from the gas distribution device.

A spindle 20 is arranged within the chamber so that the central axis 22 of the spindle extends in the upward and downward directions. The spindle is mounted to the chamber by a conventional rotary pass-through device 25 incorporating bearings and seals (not shown) so that the spindle can rotate about axis 22, while maintaining a seal between the spindle and the wall of chamber 8. The spindle has a fitting 24 at its top end, i.e., at the end of the spindle closest to the gas distribution device 12. As further discussed below, fitting 24 is an example of a wafer carrier retention mechanism adapted to releasably engage a wafer carrier. In the particular embodiment depicted, the fitting 24 is a generally frustoconical element tapering toward the top end of the spindle and terminating at a flat top surface. A frustoconical element is an element having the shape of a frustum of a cone. Spindle 20 is connected to a rotary drive mechanism 26 such as an electric motor drive, which is arranged to rotate the spindle about axis 22.

A heating element 70 is mounted within the chamber and surrounds spindle 20 below fitting 24. The chamber is also provided with an entry opening 72 leading to an antechamber 76, and a door 74 for closing and opening the entry opening. Door 74 is depicted only schematically in FIG. 1. and is shown as movable between the closed position shown in solid lines, in which the door isolates the interior of chamber 8 from antechamber 76, and an open position shown in broken lines at 74′. The door 74 is equipped with an appropriate control and actuation mechanism for moving it between the open position and closed positions. In practice, the door may include a shutter movable in the upward and downward directions as disclosed, for example, in U.S. Pat. No. 7,276,124, the disclosure of which is hereby incorporated by reference herein. The apparatus depicted in FIG. 1 may further include a loading mechanism (not shown) capable of moving a wafer carrier from the antechamber 76 into the chamber and engaging the wafer carrier with the spindle in the operative condition, and also capable of moving a wafer carrier off of the spindle and into antechamber 76.

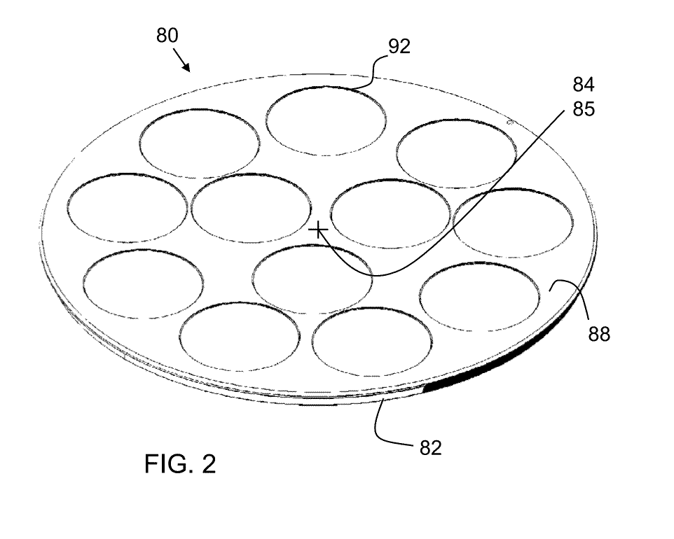

The CVD apparatus operates with a wafer carrier 80, illustrates in greater detail in FIG. 2. Wafer carrier 80 is symmetric about central axis 84. Each wafer retention site is in the form of a generally circular recess, or pocket 92 extending downwardly into the body 82 from the top surface 88. In the operating state shown in FIG. 1, a first wafer carrier 80 is disposed inside chamber 8 in an operative position, whereas a second wafer carrier 80 is disposed within antechamber 76. Each wafer carrier 80 includes a body 82 which is substantially in the form of a circular disc having a central axis 84 (FIG. 2). The body 82 is formed symmetrically about central axis 84. In the operative position the central axis 84 of the wafer carrier body is coincident with the axis 22 of the spindle. Wafer carrier 80 includes a tool interface 85 that is constructed to mechanically engage with the spindle fitting 24 of the spindle when the wafer carrier is in the operative position in the chamber. In various embodiments, tool interface 85 can take a variety of forms. For instance, in one embodiment, tool interface 85 is in the form of a recess machined into the bottom of wafer carrier body 82. In another embodiment, tool interface 85 is in the form of a separate fitting that is attached to body 82.

The body 82 desirably is formed from materials which do not contaminate the process and which can withstand the temperatures encountered in the process. For example, the larger portion of the disc may be formed largely or entirely from materials such as graphite, silicon carbide, or other refractory materials. The body 82 has a generally planar top surface 88 and a bottom surface 90 extending generally parallel to one another and generally perpendicular to the central axis 84 of the disc. Overall, wafer carrier 80 has an outer form factor that corresponds to the process chamber in which it is to be used. The outer form factor has boundaries based on the required operational clearances with respect to interior surfaces and other features within the process chamber that must be maintained according to the particular mechanical design of the tool.

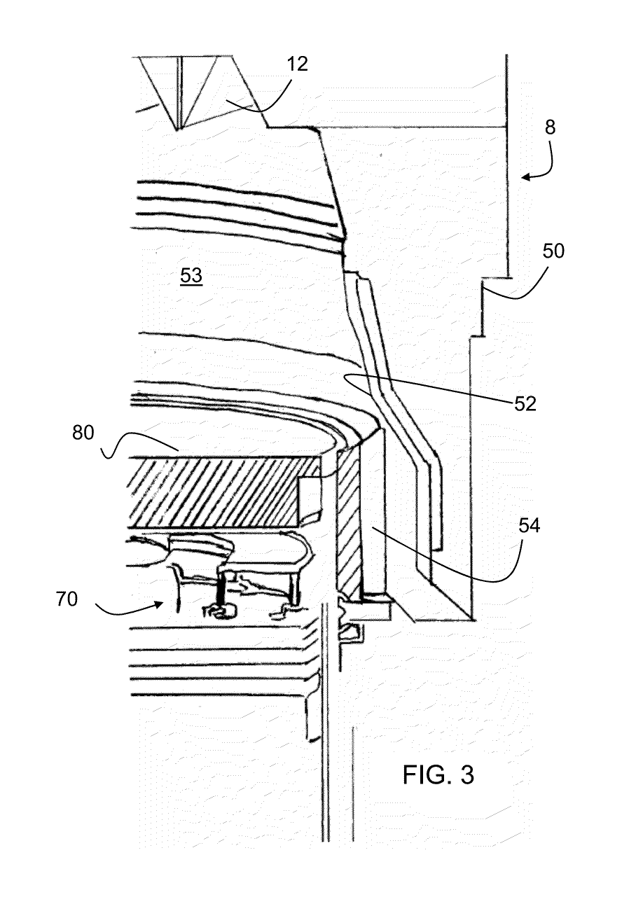

FIG. 3 is a partial cut-away view diagram illustrating additional parts of the process chamber 8. Shutter 52 provides a controlled isolation between reaction space 53 and outer wall 50 of process chamber 8. Shutter 52 includes controllable vents that can be opened or closed to varying degree in order to regulate the process gas pressure in reaction space 53. Flow extender 54 is a ring-shaped structure that is situated round the edge of wafer carrier 80. Flow extender 54 is used to provide a more uniform flow pattern for the process gasses, and more uniform heating of the outer-most portions of wafer carrier 80.

Referring again to FIG. 1, in operation, a wafer 124, such as a disc-like wafer formed from sapphire, silicon carbide, or other crystalline substrate, is disposed within each pocket 90 of each wafer carrier 80. A wafer carrier 80 with wafers loaded thereon is loaded from antechamber 76 into chamber 8 and placed in the operative position shown in FIG. 1. In this condition, the top surfaces of the wafers face upwardly, towards the gas inlet structure 12. Heater 70 is actuated, and the rotary drive mechanism 26 operates to turn spindle 20 and hence wafer carrier 80 around axis 22. Generally, the spindle is rotated at a rotational speed from about 50-1500 revolutions per minute, most typically on the order of about 1000 revolutions per minute. Process gas supply units 14a, 14b, and 14c are actuated to supply gases through the gas distribution device 12. The gases pass downwardly toward the wafer carrier 80, over the top surface 88 of the wafer carrier and the top surfaces 126 of the wafers, and downwardly around the periphery of the wafer carrier to the outlet and to exhaust system 18. Thus, the top surface of the wafer carrier and the top surfaces of the wafer are exposed to a process gas including a mixture of the various gases supplied by the various process gas supply units. Most typically, the process gas at the top surface is predominantly composed of the carrier gas supplied by carrier gas supply unit 14b. In a typical chemical vapor deposition process, the carrier gas may be nitrogen, and hence the process gas at the top surface of the wafer carrier is predominantly composed of nitrogen with some amount of the reactive gas components.

Heaters 70 transfer heat to the bottom surface 90 of the wafer carrier, principally by radiant heat transfer. The heat applied to the bottom surface of the wafer carrier flows upwardly through the body 82 of the wafer carrier to the top surface 88 of the wafer carrier. Heat passing upwardly through the body also passes upwardly through gaps to the bottom surface of each wafer, and upwardly through the wafer to the top surface 126 of the wafer. Heat is radiated from the top surface 88 of the wafer carrier and from the top surfaces 126 of the wafer to other parts of the process chamber such as, for example, to the walls of the process chamber and to the gas distribution device 12. Heat is also transferred from the top surface 88 of the wafer carrier and the top surfaces 126 of the wafers to the process gas passing over these surfaces.

In some embodiments, temperature monitor 94 and temperature profiling system 96 are used as parts of a monitoring system to determine the spatial distribution of heat applied to the surfaces of the wafers during processing.

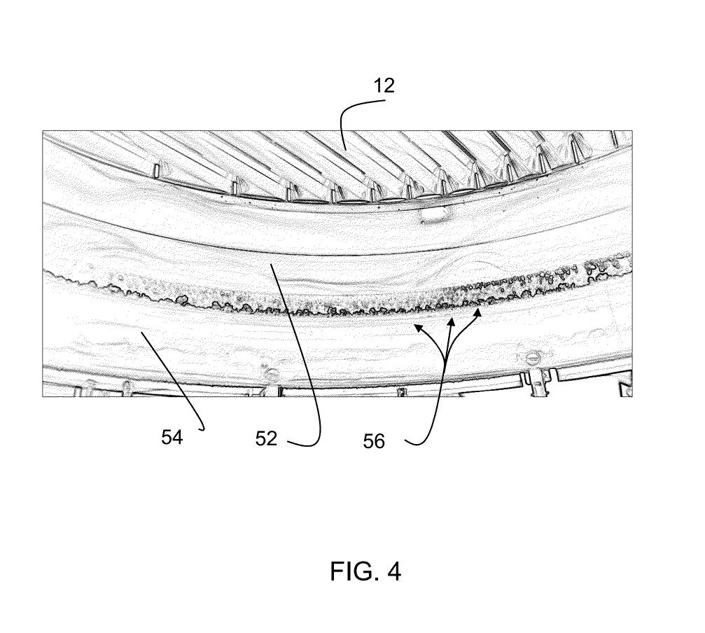

In a related embodiment, gas inlet structure 12 is heated to increase the temperature of the gas as it enters the process chamber. Higher-temperature gas reduces the thermal gradient in the wafers as most of the heat is applied through their bottom surface. This, in turn, reduces thermally-induced deformation, e.g., bowing, of the wafers. As an unintended consequence, the increased gas temperature results in more of the reactive gasses depositing material on interior surfaces of the wafer chamber, particularly on the flow extender and shutter. FIG. 4 is a diagram illustrating the interior of reaction space 53 in which GaN deposits 56 have formed on the surfaces of shutter 52 and FE 54.

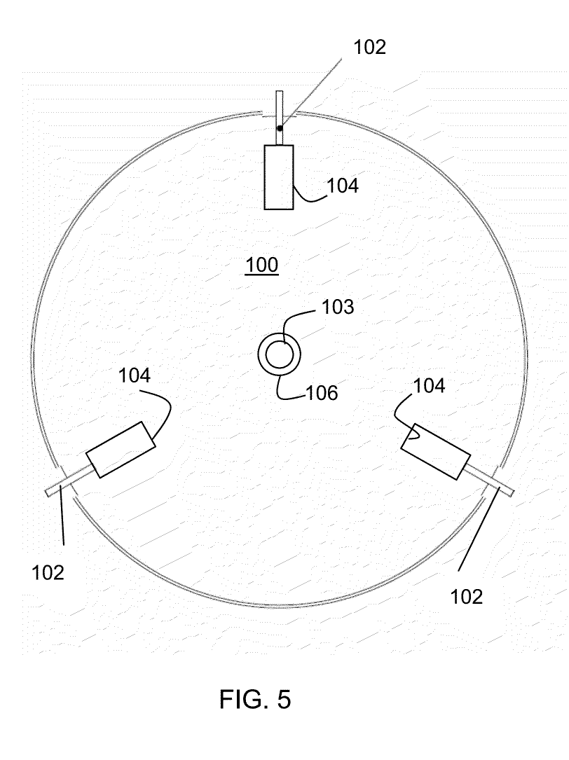

FIG. 5 is a schematic diagram illustrating a solution for efficient in-situ removal of undesired material deposits 56 on the interior of the process chamber 8 according to aspects of the invention. The in-situ cleaning is achieved by not having to disassemble the process chamber 8 to perform the cleaning operation. Instead, according to this solution, a cleaning mechanism is deployed using existing, non-specialized, functionality of the CVD tool in conjunction with a specialized cleaning carrier.

According to one type of embodiment, a cleaning carrier 100 is utilized to clean nearby surfaces. Cleaning carrier 100 is constructed to have a similar size, shape, and mass as an actual wafer carrier 80, and includes tool interface 103 that is similar to that of a wafer carrier 82. These similarities allow the cleaning carrier 100 to be automatically handled by the CVD system in the same manner in which an actual wafer carrier 80 is handled. Thus, for example, cleaning carrier 100 is constructed to be placed on spindle 20 and rotated according to a particular recipe.

The materials from which the body of cleaning carrier 100 is made include aluminum alloy, stainless steel, and any other suitable material (or combination of materials). Factors that may be considered in selecting an appropriate material for a particular application are cost, ease of machining, vacuum/gas compatibility, durability, temperature rating, density, and effect on processing. In one related embodiment, the mass distribution of cleaning carrier 100 is specifically made to differ from wafer carrier 80 in order to increase the moment of inertia of cleaning carrier 100 to smooth out any sudden changes in loading on the drive mechanism possibly caused by operation of the cleaning carrier 100 in a cleaning process.

In terms of dimensions, cleaning carrier 100 has a form factor that corresponds to (i.e., matches, fits within, or does not substantially exceed) the outer form factor of wafer carrier 80 that corresponds to the process chamber in which it is to be used. Thus, cleaning carrier 100 practically respects the required clearances within the process chamber so that cleaning carrier 100 is compatible with the process chamber with which it is to be used.

Instead of having wafer retention sites that an actual wafer carrier 82 has, cleaning carrier 100 includes a set of deployable brushes 102 that can move from a normally retracted position to a deployed position. In one type of embodiment, the deployable brushes 102 are deployed in response to a condition established in the process chamber, such as rotation of the spindle, temperature change, pressure change, etc.

When deployed, brushes 102 protrude beyond the outer form factor that a wafer carrier would ordinarily fit within, and the brushes 102 engage with specific interior surfaces of the process chamber 8. Rotation of the cleaning carrier 100 on spindle 20 causes the brushes to scrub those specific interior surfaces to remove any material deposits. Brushes 102 have a cleaning element, such as a set of bristles, that works to remove deposited material from the surfaces to be cleaned. It should be noted that, in various other embodiments, the cleaning element of the brush may have a structure other than bristles. Examples include a textured surface, an elastomeric surface, a polishing structure, an abrasive structure, or the like. Thus, the term brush as used herein can include any one, or a combination, of a variety of contemplated mechanical cleaning elements for removing material from a surface.

Deployment and refraction mechanism 104 is situated near the outer periphery of cleaning carrier 100. Deployment and retraction mechanism 104 operates to retain the brushes 102 in the retracted position in the absence of a cleaning process, and to deploy the brushes in response to an applied condition by operation of the cleaning process. In one particular embodiment, the condition applied by operation of the cleaning process is rotation of the cleaning carrier 100, which applies centripetal forces to the deployment and retraction mechanism 104 and brush 102.

In a related embodiment, examples of which are described in greater detail below, cleaning carrier 100 includes an anti-slip mechanism 106 that operates to more tightly couple the wafer carrier to the drive mechanism. This feature is useful by itself, or in conjunction with the cleaning brushes, which cause friction with interior surfaces of the process chamber that can, in turn, cause slippage between the drive mechanism and cleaning carrier. In a related embodiment, the anti-slip mechanism is engaged in response to the applied condition by operation of the cleaning process, and to otherwise normally disengage. In a particular embodiment, which is described in detail below, the anti-slip mechanism 106 is in the form of a clamping mechanism that is adapted to grip the spindle of the drive mechanism.

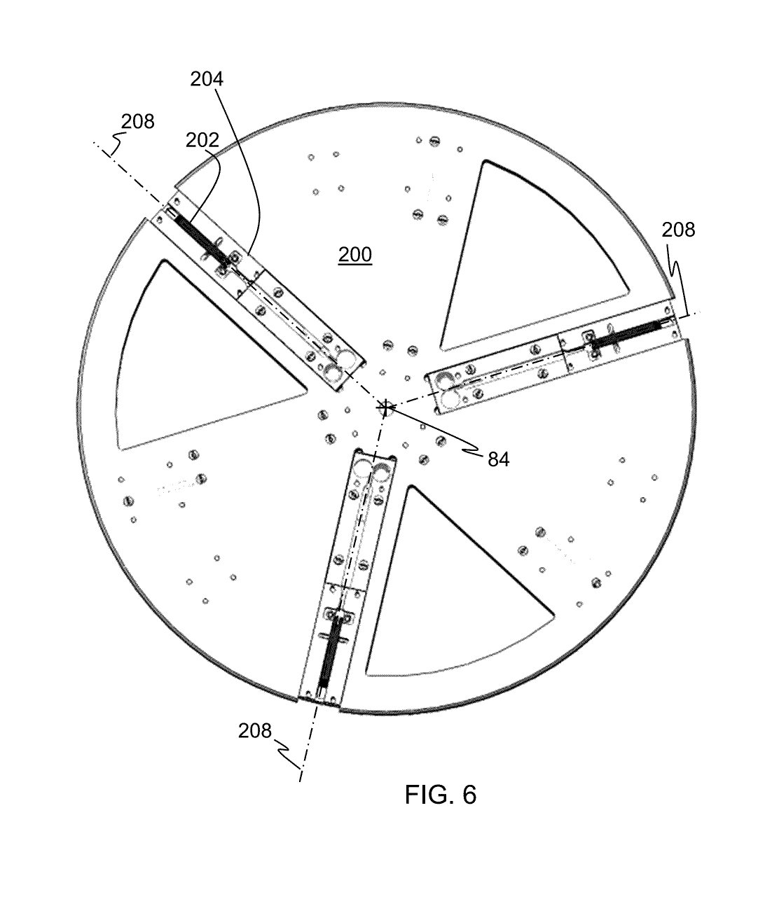

FIG. 6 is a top view diagram illustrating cleaning carrier 200 in greater detail according to one embodiment. Cleaning carrier 200 is presented as an exemplary embodiment of cleaning carrier 100. Each brush 202 is retained by a corresponding deployment and retraction mechanism 204. As depicted, in this embodiment each brush 202 and corresponding deployment and retraction mechanism 204 is arranged along a corresponding radial axis 208. In addition, the groups of brush 202 and deployment and retraction mechanism 204 are arranged at equal angles about central axis 84. Thus, each radial axis 208 in this embodiment, where there are three groups of brush 202 and deployment and retraction mechanism 204, is offset by 120 degrees. This type of arrangement provides a balanced mass distribution about the central axis of the cleaning carrier 200 so that the cleaning carrier does not wobble as it is rotated during a cleaning process. In other embodiments, there may be two brushes situated at 180 degrees from one another, four brushes at 90-degree positions, five brushes at 72-degree positions, etc.

It is also contemplated that in other embodiments (not shown) the brushes may have bifurcated ends such as y-shaped forked arms with a cleaning element at each forked end. More generally, aspects of the invention relate to any brush geometry that can be suitable for cleaning an one or more interior chamber surfaces.

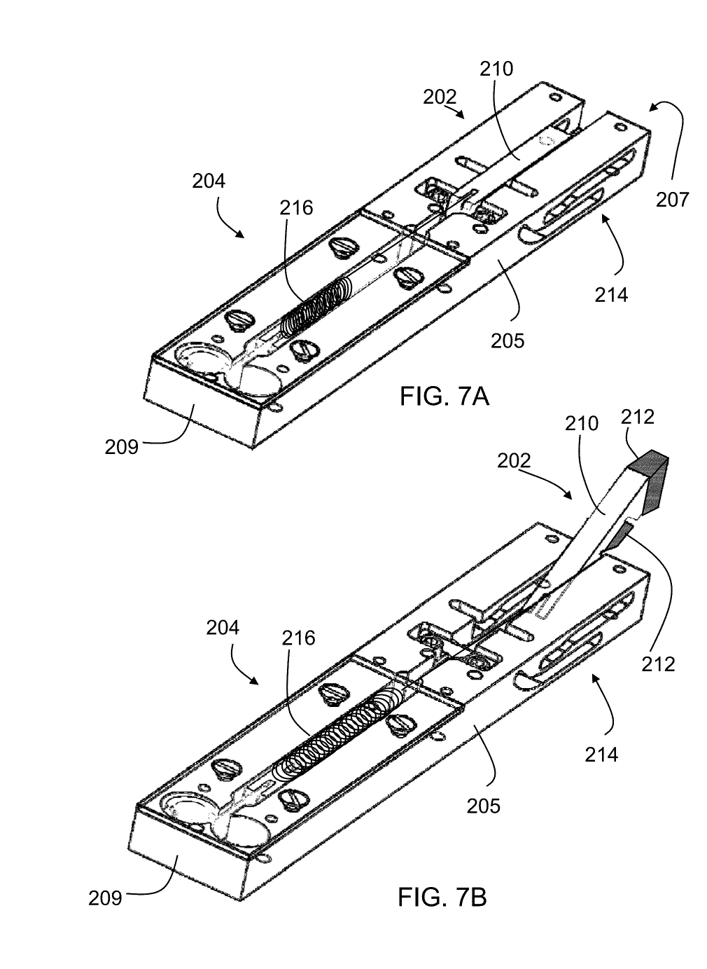

FIGS. 7A and 7B illustrate in perspective view brush deployment and retraction mechanism 204, with brush 202 retracted and deployed, respectively. Brush deployment and retraction mechanism 204 includes a body 205 having various recesses, cutouts, and other features for retaining and repositioning brush 202. In one embodiment, as shown, brush deployment and refraction mechanism 204 is fully recessed within the outer boundaries of body 205; though in other embodiments the deployment and retraction mechanism can protrude beyond the outer boundary of body 205 (while remaining within the outer form factor of an ordinary wafer carrier so as not to interfere with interior surfaces of the process chamber when the brushes are not deployed).

In the embodiment depicted in this example, brush 202 includes a movable arm 210 that is slidably coupled to body 205 via a track. In this particular case, the track is in the form of guide cutout 214, described in greater detail below. In various other embodiments, the track can take other forms, e.g., one or more grooves, rails, bearings, etc. Brush 202 has a cleaning element at its distal end. In the embodiment shown, the cleaning element is in the form of bristles 212 made from a suitable material to provide sufficient cleaning performance without damaging the surface to be cleaned. The location and profile of bristles 212 is designed to correspond to the profile of the surface to be cleaned. Suitable materials for the bristles include, without limitation, metal wire strands, polymer strands, strands made from composite material, or any combination thereof.

In its retracted position, brush 202 is entirely recessed within the boundaries of body 205 according to this particular embodiment, though in other embodiments it may be sufficient for the distal end of brush 202 to be retracted within the form factor ordinarily occupied by a wafer carrier (e.g., so as to not protrude substantially past distal end 207 of body 205).

Brush 202 is normally held in its retracted position due to the operation of biasing member 216, which urges proximal end of arm 210 towards proximal end 209 of body 205. In the particular example depicted, biasing member 216 is in the form of a tension coil spring, though in various other embodiments entirely different biasing members are contemplated. For instance, biasing member may be a compression element that is situated near the distal end 207 of member 205 and pushes, rather than pulls, arm 210. Also, various materials and structures for biasing member 216 are contemplated, such as those made from elastomeric materials.

In operation, the biasing force of biasing member 216 is overcome to reposition brush 202 from its retracted position into its deployed position. In the exemplary embodiment depicted, the rotation of cleaning carrier 200 causes brush 202 to experience a centrifugal force (i.e., towards distal end 207 of body 205). This centrifugal force applied to the mass of brush 202 exceeds the tension force of the tension coil spring biasing member 216, causing brush 202 to slidably deploy outwards, i.e., towards the distal end 207, along guide cutouts 214. In one particular embodiment, the biasing force of biasing member 216 is designed to correspond to a particular minimum rotation speed below which the brushes 202 cannot deploy.

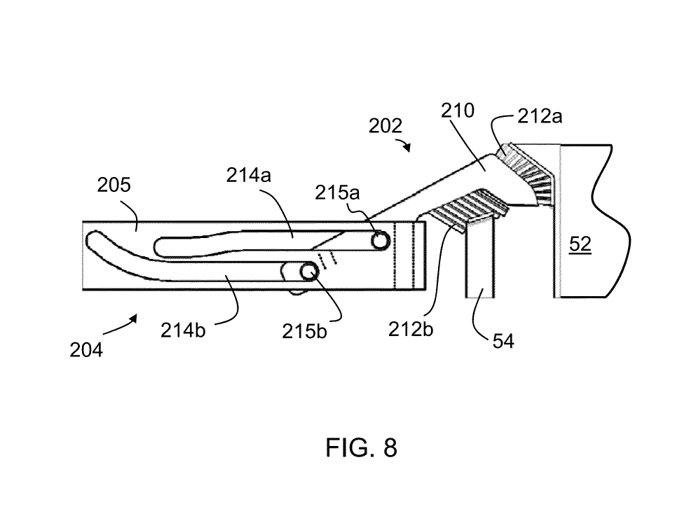

FIG. 8 is a side-view diagram of brush 202 and deployment and retraction mechanism 204 according to one embodiment. As depicted, the brush 202 is deployed and in position to clean surfaces of shutter 52 and flow extender 54. In this example, guide cutouts 214 are a pair of upper guide cutouts 214a and lower guide cutouts 214b on opposite sides of body 214, along which lateral retention pins 215a and 215b, respectively, slide. Upper guide cutout 214a and lower guide cutout 214b are shaped such that brush 202 deploys outwards and pivots upwards. A first set of bristles 212a are specifically arranged to correspond to a portion of the surface of shutter 52 to be cleaned. A second set of bristles 212b are arranged to clean the surface top surface flow extender 54.

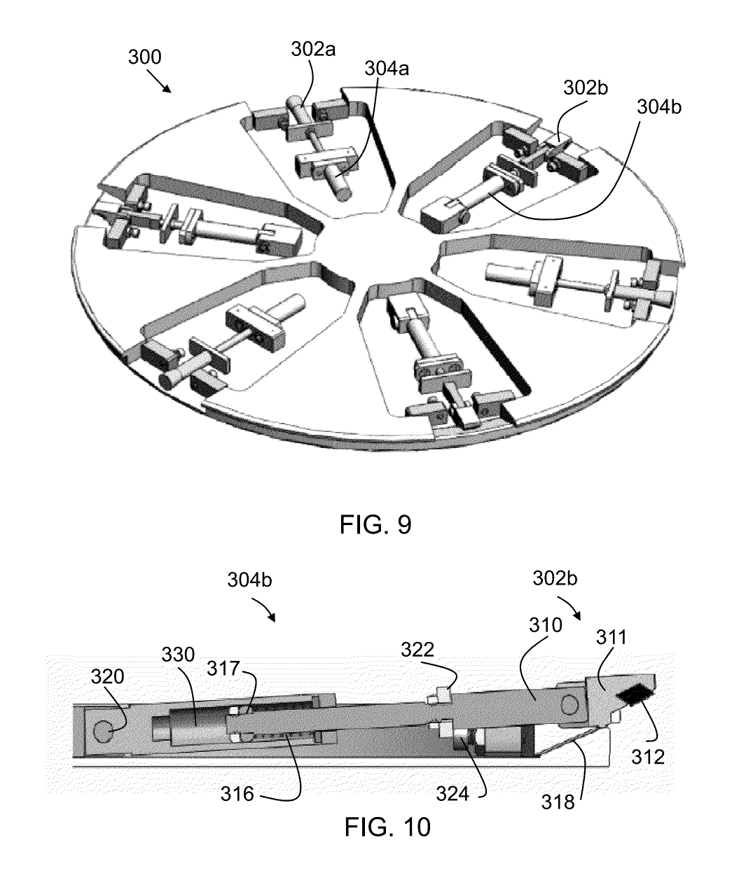

FIG. 9 is a perspective view diagram illustrating a cleaning carrier 300 according to another embodiment of cleaning carrier 100. In this embodiment, brushes 302a are dedicated to cleaning the inside-facing surface of the flow extender, whereas brushes 302b are dedicated to cleaning the top surface of the flow extender. Brushes 302a are configured to deploy outwardly only, whereas brushes 302b are configured to deploy outwardly and upwardly.

FIG. 10 is a partial cut-away diagram illustrating brush 302b and deployment/retraction mechanism 304b in greater detail. As depicted, brush 302b is deployed. Brush 302b includes arm 310, at the distal end of which a brush head 311 is attached. Brush head 311 has a scrubbing surface 312 (e.g., bristles) positioned to scrub the top surface of the flow extender.

In the absence of rotation, biasing member 316 (which in this example is a compression coil spring) pushes on piston end 317 to retract brush 302b. In operation, centrifugal forces experienced by brush 302b overcome the force of biasing member 316 to cause outward movement of arm 310. Ramp 318 and pivot 320 allow arm 310 to tilt upwards as it move outwards. Stopper 322 butts up against bumper 324 at the set distance when the arm brush 302b is fully deployed.

In related embodiments, other process-induced conditions are utilized to deploy the brushes. In one such embodiment, instead of the centripetal/centrifugal forces applied to deploy the brushes, a reduced pressure in the chamber is employed. In this embodiment, referring to FIG. 10, biasing member 316 is omitted. Instead, gas is contained in cavity 330 at or below atmospheric pressure. When a full or partial vacuum is established inside the material deposition chamber, the gas expands, pushing the piston connected to brush head 311 outward. Applied heat in the process chamber can also cause expansion of the gas in the cylinder.

In another related embodiment, heat-activated materials are used to deploy the brushes. When the temperature is raised in the process chamber, the heat-activated materials change their shape and, either directly, or through a movement magnification mechanism such as a lever, exert an outward force on the brushes so as to deploy them.

In another type of embodiment, the brushes can be deployed using one or more electromechanical actuators that can be controlled to activate and deploy brushes in response to process conditions such as raised temperature, reduced pressure, rotation, etc., or in response to applied electromagnetic signaling, such as RF, IR, etc.

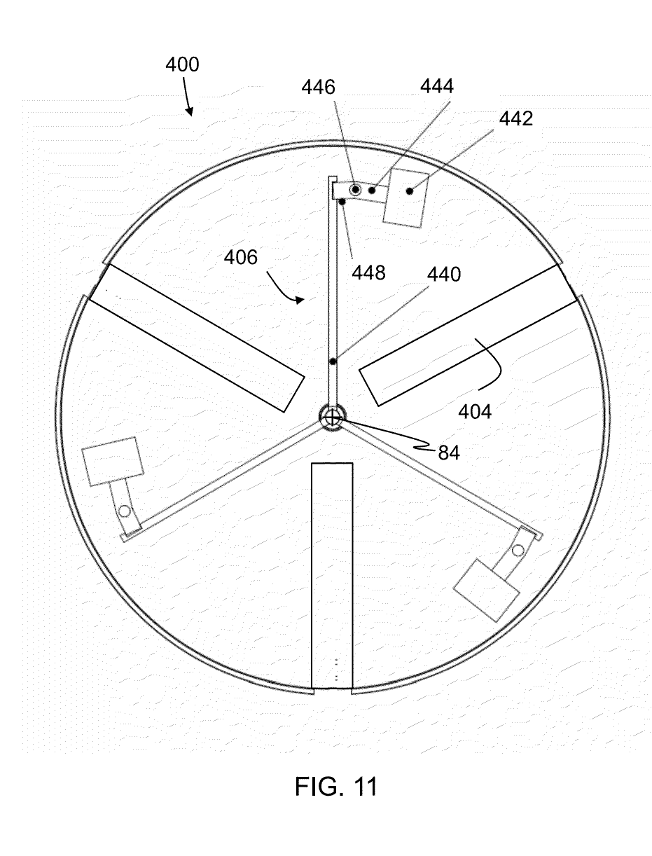

FIG. 11 is a schematic diagram illustrating a cleaning carrier 400 that features an anti-slip spindle clamping mechanism 406 according to one embodiment. The spindle clamping mechanism 406 is an example embodiment of anti-slip mechanism 106 described above. Spindle clamping mechanism 406 is designed to grab the spindle 20 to more tightly couple cleaning carrier 400 to the rotary drive 26. In one embodiment, spindle clamping mechanism 406 utilizes a condition applied to cleaning carrier 400 by operation of a cleaning process.

In one particular application, spindle clamping mechanism 406 is used in conjunction with the cleaning brushes in a cleaning carrier 100 to prevent or reduce slippage of the cleaning carrier due to the friction created when scrubbing the surfaces subjected to cleaning with the brushes. Accordingly, in a related embodiment of cleaning carrier 400, brush retention and deployment mechanisms 404 are included.

Clamping mechanism 406 includes a group of rods 440 situated radially, and evenly spaced about central axis 84. At the proximal end of each rod 440 is a clamping surface constructed to engage with the shaft on which cleaning carrier 400 spins. At the distal end of each rod 440 is a movable mass 442 mounted at a first end of lever 444. Lever 444 pivots at fulcrum 446. At the second end of lever 444 is a connection to rod 440.

Movement of mass 442 in the distal direction (such as in response to centrifugal forces felt by mass 442) causes rod 440 to move in the proximal direction, i.e., towards central axis 84. Fulcrum 446 is positioned along the length of lever 444 to increase the force applied to the rod 440. Rod 440 slides along a radially-oriented channel (not shown), which may be in the form of an elongate recess or groove.

Biasing member 448 is arranged to urge clamping mechanism 406 to move to the released position. Therefore, in operation, the process condition applied to cleaning carrier 400 must be sufficient to overcome the biasing force of biasing member 448. In various embodiments, biasing member 448 is in the form of a spring (e.g., compression coil spring, tension coil spring, etc.), or some other suitable resilient or elastic material and structure for applying tension or compression.

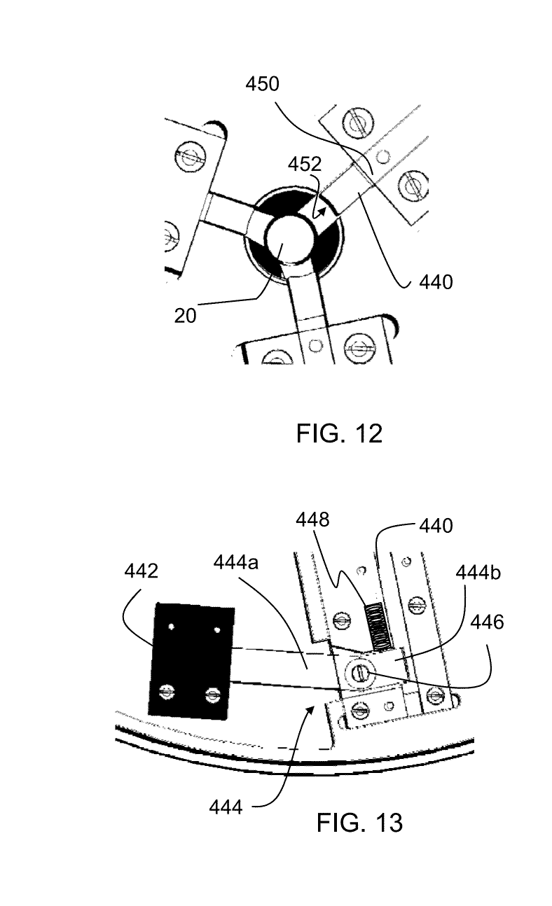

FIG. 12 is a close-up view diagram of the spindle clamping part of clamp mechanism 406 according to one embodiment. Rod 440 is moved radially along channel 450. At the proximal end of rod 440 is clamping surface 452. In the embodiment shown, clamping surface 452 has a curvature that corresponds to the curvature of spindle 20. In a related embodiment, surface 452 has a friction-increasing provision such as a texturing or coating (e.g., elastomer or polymer).

FIG. 13 is a close-up view diagram of the clamping mechanism activation portion on the distal end from the spindle. Movable mass 442 is mounted to the long arm 444a of the lever 444. On the other side of fulcrum 446 is short arm 444b that engages with rod 440. Movement of the mass 442 in the distal direction, which in FIG. 13 is downward, causes upward motion, i.e., toward spindle 20, of short arm 444b and rod 440. In one particular embodiment, the ratio of the lever is about 2.5:1 and the mass is about 120 grams. However, various other embodiments are contemplated where these values may be different. In general, one approach in selecting the mass and lever ratios is to provide sufficient clamping force such that no slippage occurs between the cleaning carrier body and the spindle in view of the friction experienced from the cleaning brushes scrubbing against the interior of the process chamber and the motor drive's torque at the rotational speeds during which the brushes are deployed.

In the absence of rotation of the cleaning carrier, there is no centrifugal force experienced by the mass 442, and biasing member 448 urges long arm 444a upwards, which tends to draw rod 440 away from spindle 20.

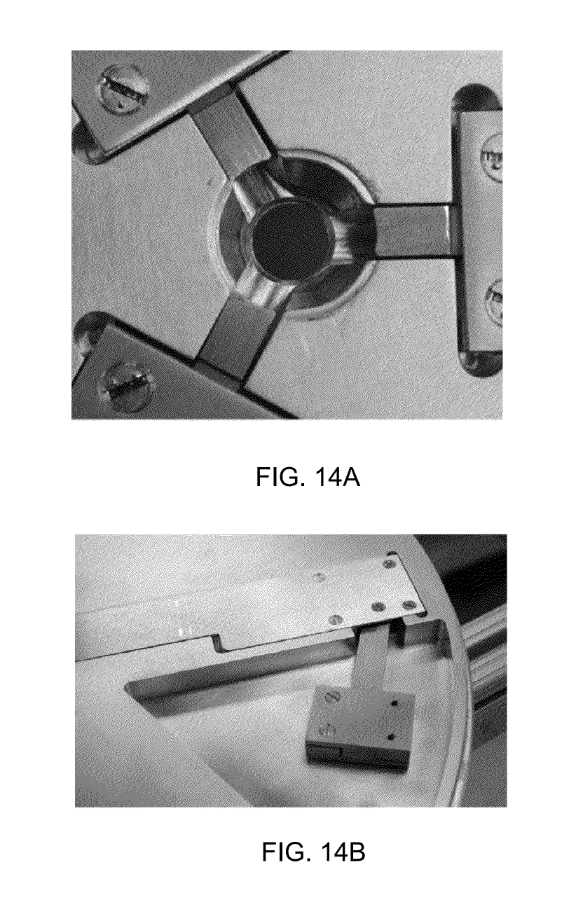

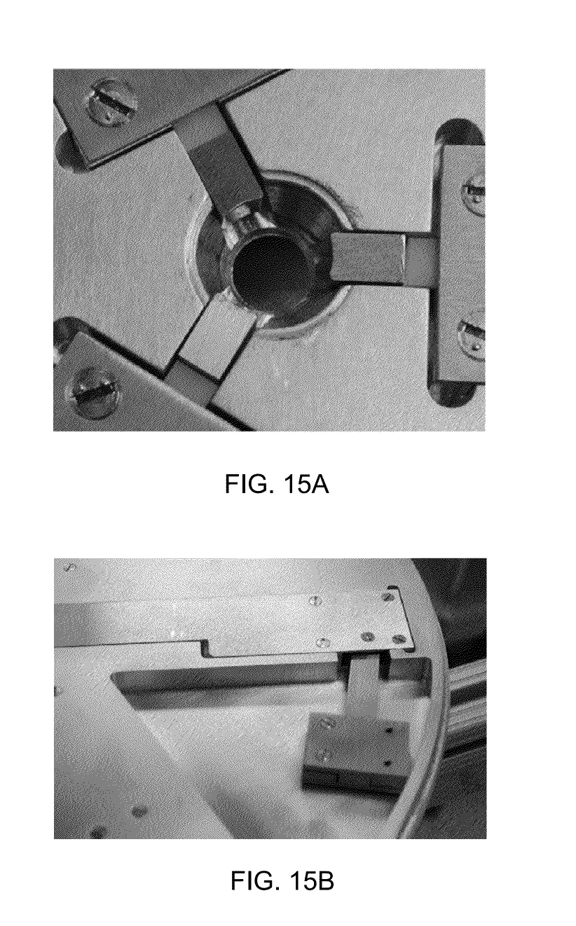

FIGS. 14A-14B illustrate the spindle clamping part and activation part, respectively, of clamping mechanism 406 in the disengaged state. FIGS. 15A-15B are counterpart illustrations showing both parts of clamping mechanism 406 in the engaged state.

Importantly, it should be noted that the spindle clamping mechanism described herein, while disclosed in conjunction with a cleaning carrier, may be utilized in applications other than cleaning. For instance, the spindle clamping mechanism embodiments may be used with an actual wafer carrier to improve coupling with the spindle of the drive mechanism. Still other applications are contemplated in which the spindle clamping mechanism is used with “dummy” carriers for other purposes.

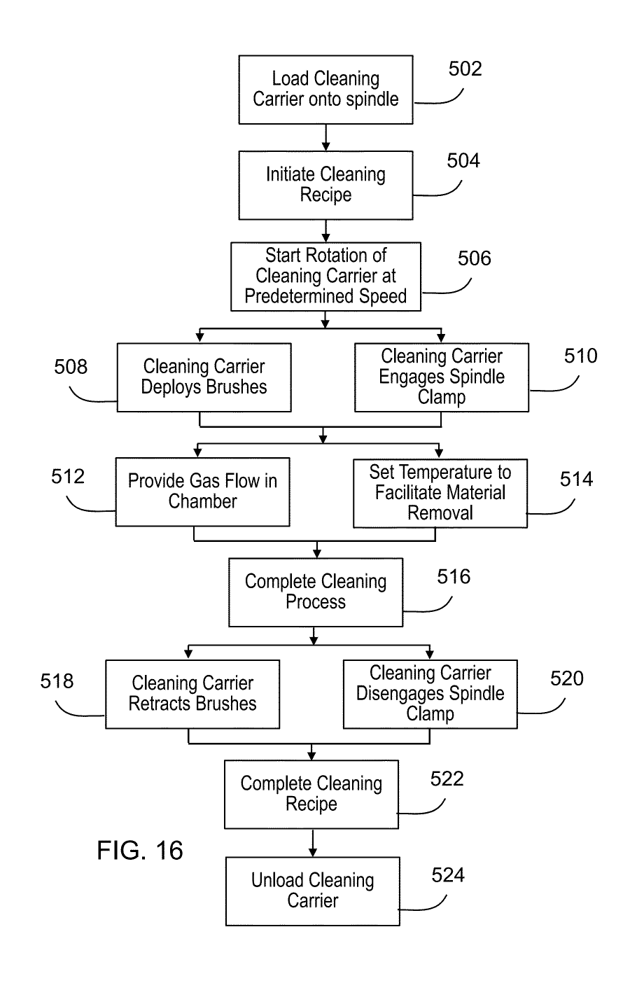

FIG. 16 is a flow diagram illustrating a process for using a cleaning carrier such as cleaning carrier 100, 200, 300, or 400, to clean interior surfaces of a material deposition tool according to one embodiment. At 502, the cleaning carrier is moved into the process chamber and loaded onto the spindle. This operation is no different from the loading of a wafer carrier such as wafer carrier 82 for a material deposition process. At 504, a cleaning recipe is initiated by the tool. The cleaning recipe differs from that of a material deposition recipe in that reactant gasses for deposition are not introduced. Other environmental conditions similar to those of a deposition process may be applied, however, such as, for example, increasing the temperature in the process chamber, or initiating air flow of an inert gas, or a reactant gas to aid in material removal according to various embodiments.

At 506, the condition of rotation of the cleaning carrier is initiated. In the cleaning recipe according to one embodiment, the target speed of rotation can be quite different from the rotation speed used in wafer processing. For instance, in a system applying speeds on the order of 1,000 RPM for wafer processing, a slower speed of around 400 RPM may be used in the cleaning recipe. In other embodiments, the cleaning recipe can use similar speeds to those used in material deposition processes, or speeds that are even faster.

In response to the applied condition which, in this example, is rotation of the cleaning carrier, the brushes are deployed by the cleaning carrier at 508. As in some of the embodiments described above, a centrifugal mechanism is used to deploy the brushes, though other deployment mechanisms may also be used in other embodiments as described above, in which the brushes are deployed in response to an environmental change in the process chamber. At 510, in embodiments having a spindle clamp, the clamp engages to grab the spindle. As with the deployment mechanism of the brushes, the spindle clamp engagement mechanism may operate on a centrifugal principle, or based on another process environment change. The deployment of the brushes at 508 and engagement of the spindle clamp at 510 can occur simultaneously, or in any order, depending on the particular configuration of these mechanisms in the cleaning carrier.

At 512, gas flow is provided in the process chamber according to one embodiment. The function of the gas flow is to carry away the removed particulate matter from operation of the brushes to the effluent channel of the process chamber. In one implementation, inert gas is used; whereas in another approach a reactive gas component is used to assist with desorption of the material from the surfaces being cleaned. In another related embodiment, at 514, the process chamber is heated to assist with the removal of material. In this embodiment, a temperature at which the deposited material tends to more easily release from the surface being cleaned is preferably utilized. The order in which the temperature is raised at 514 and gas flow 512 is provided can vary according to different embodiments. Likewise, any of these operations may take place before or after the deployment of brushes and engagement of the spindle clamp at 508 and 510, respectively.

The cleaning operation in which the brushes clean their corresponding surfaces continues for a predetermined time according to the cleaning recipe, or until the occurrence of a certain event indicative of the completion of the cleaning, such as a detection of cessation of particulate material in the effluent channel. Subsequently, at 516, the cleaning process is wound up. Accordingly, rotation of the cleaning carrier is decelerated until the carrier stops, and the supply of gas flow and heating, where used, is ceased. During the deceleration, in the centrifugal embodiments, at 518 and 520, respectively, the cleaning carrier retracts the brushes at 518, and the cleaning carrier disengages the spindle clamp at 510 if the clamp is employed. In the other, non-centrifugal, embodiments, the cessation of environmental conditions which caused deployment of the brushes and engagement of the spindle clamp causes these mechanisms to return to their nominal state of retraction and disengagement. At 522, the cleaning recipe is completed and, at 524, the cleaning carrier is unloaded from the process chamber in similar fashion to the unloading of a wafer carrier.

The embodiments above are intended to be illustrative and not limiting. Additional embodiments are within the claims. In addition, although aspects of the present invention have been described with reference to particular embodiments, those skilled in the art will recognize that changes can be made in form and detail without departing from the scope of the invention, as defined by the claims.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention may comprise a combination of different individual features selected from different individual embodiments, as will be understood by persons of ordinary skill in the art.

Any incorporation by reference of documents above is limited such that no subject matter is incorporated that is contrary to the explicit disclosure herein. Any incorporation by reference of documents above is further limited such that no claims that are included in the documents are incorporated by reference into the claims of the present Application. The claims of any of the documents are, however, incorporated as part of the disclosure herein, unless specifically excluded. Any incorporation by reference of documents above is yet further limited such that any definitions provided in the documents are not incorporated by reference herein unless expressly included herein.

For purposes of interpreting the claims for the present invention, it is expressly intended that the provisions of Section 112, sixth paragraph of 35 U.S.C. are not to be invoked unless the specific terms “means for” or “step for” are recited in a claim.

What is claimed is:

1. A cleaning carrier for in-situ cleaning of a process chamber of a material deposition tool that is adapted for use with a removable wafer carrier, the removable wafer carrier having an outer form factor defined based on predefined operational clearances within the process chamber, the cleaning carrier comprising:
a cleaning carrier body formed symmetrically about a central axis and having outer boundaries corresponding to the outer form factor of the removable wafer carrier;
a tool interface that facilitates mounting of the cleaning carrier body on a portion of the material deposition tool that accepts the removable wafer carrier;
a set of deployable and retractable brushes operatively coupled with the cleaning carrier body via a corresponding set of deployment and retraction mechanisms, the brushes being movable between a retracted position and a deployed position such that in the retracted position, the brushes are situated within the outer form factor and, in the deployed position, the brushes protrude beyond the outer form factor.

2. The cleaning carrier of claim 1, wherein the cleaning carrier body has outer boundaries fitting entirely within the outer form factor of the removable wafer carrier.

3. The cleaning carrier of claim 1, wherein the set of deployment and retraction mechanisms and the brushes are arranged such that the brushes are recessed within the cleaning carrier body when in the retracted position.

4. The cleaning carrier of claim 1, wherein each brush of the set of brushes comprises an arm having a proximal and a distal end, and at least one cleaning element situated at the distal end and, when the brushes are in their deployed position within the process chamber, the at least one cleaning element of each brush makes direct contact with an interior surface of the process chamber.

5. The cleaning carrier of claim 4, wherein the interior surface of the process chamber with which the brushes, in their deployed position, make contact is a surface selected from the group consisting of: an interior surface of a flow extender, an interior surface of a shutter, or any combination thereof.

6. The cleaning carrier of claim 1, wherein each brush of the set of brushes comprises a plurality of differently-oriented cleaning elements adapted to clean a corresponding plurality of differently-oriented interior surfaces of the process chamber.

7. The cleaning carrier of claim 1, wherein each brush of the set of brushes comprises at least one cleaning element having a set of bristles.

8. The cleaning carrier of claim 1, wherein the set of deployment and retraction mechanisms is constructed to deploy the set of brushes in response to a process condition established in the process chamber.

9. The cleaning carrier of claim 8, wherein the process condition established in the process chamber in response to which the set of brushes is deployed includes rotation of the cleaning carrier that applies a centripetal force to the set of brushes.

10. The cleaning carrier of claim 8, wherein the process condition established in the process chamber in response to which the set of brushes is deployed is selected from the group consisting of: a change in temperature, a change in pressure, or any combination thereof.

11. The cleaning carrier of claim 1, wherein each mechanism of the set of deployment and retraction mechanisms includes a track on which a corresponding brush slides along a radial direction relative to the center of the cleaning carrier.

12. The cleaning carrier of claim 11, wherein the track includes guide cutouts situated generally along a radial direction relative to the central axis, and wherein each brush includes an arm that is movably retained by the guide cutouts such that the arm is permitted to move along the guide cutouts.

13. The cleaning carrier of claim 1, wherein when in the deployed position, the brushes protrude above an upper-most surface of the cleaning carrier body.

14. The cleaning carrier of claim 1, wherein each mechanism of the set of deployment and retraction mechanisms includes a biasing member that is configured to apply a biasing force urging movement of the brushes into the retracted position.

15. The cleaning carrier of claim 1, wherein the tool interface comprises:
an anti-slip mechanism operatively coupled to the cleaning carrier body and constructed to engage and disengage a drive mechanism of the material deposition tool on which the wafer carrier rotates during operation, wherein the engagement with the drive mechanism increases a degree of coupling between the cleaning carrier body and the drive mechanism so as to reduce slippage between the drive mechanism and cleaning carrier during the rotation.

16. The cleaning carrier of claim 15, wherein the anti-slip mechanism is constructed to engage the drive mechanism in response to a change in process condition established in the process chamber.

17. The cleaning carrier of claim 15, wherein the anti-slip mechanism comprises a clamping mechanism adapted to frictionally engage with, and disengage from, a spindle portion of the drive mechanism in response to rotation of the cleaning carrier.

18. The cleaning carrier of claim 17, wherein the clamping mechanism includes:
a plurality of clamping surfaces adapted to make direct contact with the spindle portion when frictionally engaging with the spindle portion; and
at least one engagement and disengagement mechanism adapted to cause movement of the clamping surfaces to grip and un-grip the spindle portion.

19. The cleaning carrier of claim 17, wherein the clamping mechanism includes a group of rods situated radially and distributed evenly about the central axis, each one of the rods being movable along radial direction between a clamped position toward the central axis, and a released position away from the central axis, and having a proximal end and a distal end, the proximal end including a clamping surface adapted to frictionally engage with the spindle portion, and the distal end being coupled to an engagement and disengagement mechanism adapted to move the rod in a radial direction toward the central axis in response to rotation of the cleaning carrier body.

20. The cleaning carrier of claim 17, wherein the engagement and disengagement mechanism includes a mass movable in a primarily distal direction in response to a centripetal force applied to it by rotation of the cleaning carrier body, and wherein the mass is coupled to a corresponding clamping surface via a linkage that causes movement of the clamping surface in a proximal direction in response to movement of the mass in the primarily distal direction, and wherein the mass is subjected to a constant biasing force urging movement of the mass in a primarily proximal direction, wherein movement of the mass in the primarily distal direction is achieved only when the centripetal force applied to the mass overcomes the biasing force.

21. A cleaning carrier for in-situ cleaning of a process chamber of a material deposition tool that is adapted for use with a removable wafer carrier, the removable wafer carrier having an outer form factor defined based on predefined operational clearances within the process chamber, the cleaning carrier comprising:
a cleaning carrier body formed symmetrically about a central axis and having outer boundaries corresponding to the outer form factor of the removable wafer carrier;
a tool interface that facilitates mounting of the cleaning carrier body on a portion of the material deposition tool that accepts the removable wafer carrier, the tool interface comprising an anti-slip mechanism operatively coupled to the cleaning carrier body and constructed to engage and disengage a drive mechanism of the material deposition tool on which the wafer carrier rotates during operation, wherein the engagement with the drive mechanism increases a degree of coupling between the cleaning carrier body and the drive mechanism so as to reduce slippage between the drive mechanism and cleaning carrier during the rotation; and
at least one cleaning element adapted to clean an interior surface of the process chamber.

22-41. (canceled)

42. Apparatus for growing epitaxial layers on one or more wafers by chemical vapor deposition (CVD), comprising:
a process chamber;
a rotatable spindle having an upper end disposed inside the process chamber;
a wafer carrier for transporting and providing a support for the one or more wafers, the wafer carrier being centrally and detachably mounted on the upper end of the spindle and being in contact therewith at least in the course of a CVD process, the wafer carrier having an outer form factor defined based on predefined operational clearances within the process chamber; and
a radiant heating element disposed under the wafer carrier for heating thereof; and
a cleaning carrier for in-situ cleaning of the interior of the process chamber;
wherein the apparatus is adapted to run a cleaning process utilizing the cleaning carrier in place of the wafer carrier; and
wherein the cleaning carrier includes:
a cleaning carrier body formed symmetrically about a central axis and having outer boundaries corresponding to the outer form factor of the removable wafer carrier;
a tool interface that facilitates mounting of the cleaning carrier body on the upper end of the spindle;
a set of deployable and retractable brushes operatively coupled with the cleaning carrier body via a corresponding set of deployment and retraction mechanisms, the brushes being movable between a retracted position and a deployed position such that in the retracted position, the brushes are situated within the outer form factor and, in the deployed position, the brushes protrude beyond the outer form factor.

43. The apparatus of claim 42, wherein the set of deployment and retraction mechanisms and the brushes are arranged such that the brushes are recessed within the cleaning carrier body when in the retracted position.

44. The apparatus of claim 42, wherein each brush of the set of brushes comprises an arm having a proximal and a distal end, and at least one cleaning element situated at the distal end and, when the brushes are in their deployed position within the process chamber, the at least one cleaning element of each brush makes direct contact with an interior surface of the process chamber.

45. The apparatus of claim 42, wherein each brush of the set of brushes comprises a plurality of differently-oriented cleaning elements adapted to clean a corresponding plurality of differently-oriented interior surfaces of the process chamber.

46. The apparatus of claim 42, wherein the set of deployment and retraction mechanisms is constructed to deploy the set of brushes in response to a process condition established in the process chamber.

47. The apparatus of claim 46, wherein the process condition established in the process chamber in response to which the set of brushes is deployed includes rotation of the cleaning carrier that applies a centripetal force to the set of brushes.

48. The apparatus of claim 42, wherein each mechanism of the set of deployment and retraction mechanisms includes a track on which a corresponding brush slides along a radial direction relative to the center of the cleaning carrier.

49. The apparatus of claim 42, wherein when in the deployed position, the brushes protrude above an upper-most surface of the cleaning carrier body.

50. The apparatus of claim 42, wherein each mechanism of the set of deployment and retraction mechanisms includes a biasing member that is configured to apply a biasing force urging movement of the brushes into the retracted position.

51. The apparatus of claim 42, wherein the tool interface comprises:
an anti-slip mechanism operatively coupled to the cleaning carrier body and constructed to engage and disengage the upper portion of the spindle, wherein the engagement with the spindle increases a degree of coupling between the cleaning carrier body and the spindle so as to reduce slippage between the spindle and cleaning carrier during the rotation.

52. The apparatus of claim 51, wherein the anti-slip mechanism is constructed to engage the spindle in response to a change in process condition established in the process chamber.

53. The apparatus of claim 51, wherein the anti-slip mechanism comprises a clamping mechanism adapted to frictionally engage with, and disengage from, the spindle in response to rotation of the cleaning carrier.

54. The apparatus of claim 53, wherein the clamping mechanism includes:
a plurality of clamping surfaces adapted to make direct contact with the spindle when frictionally engaging with the spindle portion; and
at least one engagement and disengagement mechanism adapted to cause movement of the clamping surfaces to grip and un-grip the spindle.

55. The apparatus of claim 53, wherein the clamping mechanism includes a group of rods situated radially and distributed evenly about the central axis, each one of the rods being movable along radial direction between a clamped position toward the central axis, and a released position away from the central axis, and having a proximal end and a distal end, the proximal end including a clamping surface adapted to frictionally engage with the spindle, and the distal end being coupled to an engagement and disengagement mechanism adapted to move the rod in a radial direction toward the central axis in response to rotation of the cleaning carrier body.

56. The apparatus of claim 53, wherein the engagement and disengagement mechanism includes a mass movable in a primarily distal direction in response to a centripetal force applied to it by rotation of the cleaning carrier body, and wherein the mass is coupled to a corresponding clamping surface via a linkage that causes movement of the clamping surface in a proximal direction in response to movement of the mass in the primarily distal direction, and wherein the mass is subjected to a constant biasing force urging movement of the mass in a primarily proximal direction, wherein movement of the mass in the primarily distal direction is achieved only when the centripetal force applied to the mass overcomes the biasing force.

57-72. (canceled)

73. A method for in-situ cleaning of a process chamber of a material deposition tool that is adapted for use with a removable wafer carrier, the removable wafer carrier having an outer form factor defined based on predefined operational clearances within the process chamber, the method comprising:
loading a cleaning carrier in the process chamber in place of a wafer carrier;
executing, by the material deposition tool, a cleaning process that includes rotation of the cleaning carrier;
during the cleaning process, deploying, by the cleaning carrier, a set of deployable and retractable brushes such that at least one cleaning element of each brush of the set of brushes contacts an interior surface of the process chamber and the rotation of the cleaning carrier causes that cleaning element to scrub the interior surface to remove material deposits from that surface;
at a conclusion of the cleaning process, retracting, by the cleaning carrier, the set of brushes such that each of the cleaning elements of each of the brushes ceases contact with the interior surface of the process chamber;
unloading the cleaning carrier from the process chamber.

74-86. (canceled)
